(19) United States
(12) Patent Application Publication
(10) Pub. No.: US 2026/0290478 A1
(43) Pub. Date: Sep. 24, 2026

(54) OPERATING METHOD OF STORAGE DEVICE

(71) Applicant: SK hynix Inc., Gyeonggi-do (KR)

(72) Inventors: Kyeongran Yoo, San Jose, CA (US); Dengtao Zhao, San Jose, CA (US); Sung-Taeg Kang, San Jose, CA (US); Changhyun Lee, San Jose, CA (US)

(21) Appl. No.: 19/086,031

(22) Filed: Mar. 20, 2025

(51) Int. Cl. G11C 16/34; G11C 16/10

(52) U.S. Cl. CPC G11C 16/3459; G11C 16/102; G11C 16/3404

(57) ABSTRACT

An operating method of a storage device includes performing plural program loops on target memory cells for an n-th program state, according to a double verify program (DPGM) scheme, n being a natural number between 1 to N. The plural program loops include applying, to the target memory cells, program pulses having a step size for the n-th program state according to an incremental step pulse program (ISPP) scheme. The plural program loops include varying the step size according to the n-th program state.

### BACKGROUND

### 1. Field

Embodiments of the present disclosure relate to a storage device and an operating method thereof.

### 2. Description of the Related Art

A storage system stores data in response to a request from a host system such as a computer, smartphone, or smart pad. An example of a storage system is a system configured to store data in a semiconductor memory, especially in a nonvolatile memory, such as a solid-state drive (SSD) or a memory card.

A storage system includes a storage device configured to store data and a controller configured to control the storage device. Generally, a storage device can be volatile or non-volatile. Examples of a non-volatile storage device are Read Only Memory (ROM), Programmable ROM (PROM), Electrically Programmable ROM (EPROM), Electrically Erasable and Programmable ROM (EEPROM), flash memory, Phase-change RAM (PRAM), Magnetic RAM (MRAM), Resistive RAM (RRAM), and Ferroelectric RAM (FRAM).

### SUMMARY

In an embodiment of the present disclosure, an operating method of a storage device may include performing plural program loops on target memory cells for an n-th program state, according to a double verify program (DPGM) scheme, n being a natural number greater than 1 and less than N corresponding to a number of program states. The plural program loops may include applying, to the target memory cells, program pulses having a step size for the n-th program state according to an incremental step pulse program (ISPP) scheme. The plural program loops may include varying the step size according to the n-th program state.

The varying may include applying the program pulse having a base value as an initial value of the step size for the n-th program state; and adjusting the step size from the initial value to a pre-updated value when, for the first time, one of the target memory cells has a higher threshold voltage than a pre-verification level for the n-th program state. The pre-updated value may be a sum of the base value and a pre-offset value.

The varying may further include adjusting the step size from the pre-updated value to a main-updated value when, for the first time, one of the target memory cells has a higher threshold voltage than a main verification level for the n-th program state. The main-updated value is a sum of the base value and a main-offset value.

The varying may further include keeping the step size to the main-updated value until all the target memory cells pass the main verification level for the n-th program state.

The initial value may be equal to or greater than the main-updated value. The main-updated value may be equal to or greater than the pre-updated value.

The n-th program state is a relatively lower program state among N program states.

The initial value may be equal to or less than the pre-updated value. The pre-updated value may be equal to or less than the main-updated value.

The n-th program state may be a relatively higher program state among N program states.

The varying may further include defining, as a first loop base value, the step size currently having one of the initial value, pre-updated value and main-updated value at a moment when a number of advanced program loops exceeds a first threshold; and replacing the base value with a sum of the first loop base value and a negative first offset value as a first updated base value, to continue performing the plural program loops with the first updated base value for the step size to have one of the first updated base value, a sum of the first loop base value and the pre-offset value as the pre-updated value and a sum of the first loop base value and the main-offset value as the main-updated value.

The varying may further include defining, as a second loop base value, the step size currently having one of the first updated base value, pre-updated value and main-updated value at a moment when the number of advanced program loops exceeds a second threshold greater than the first threshold; and replacing the first loop base value with a sum of the second loop base value and a negative second offset value as a second updated base value, to continue performing the plural program loops with the second updated base value for the step size to have one of the second updated base value, a sum of the second loop base value and the pre-offset value as the pre-updated value and a sum of the second loop base value and the main-offset value as the main-updated value. An absolute value of the second offset value is greater than an absolute value of the first offset value.

In another embodiment of the present disclosure, an operating method of a storage device, may include performing plural program loops on target memory cells for an n-th program state within a j-th program state group, according to a double verify program (DPGM) scheme, n being a natural number greater than 1 and less than Nj corresponding to a number of program states included in each program state group, and j being a natural number greater than 1 to J corresponding to a number of program state groups. The plural program loops may include applying, to the target memory cells, program pulses having a step size for an n-th program state within the j-th program state group according to an incremental step pulse program (ISPP) scheme. The plural program loops include varying the step size according to each of the n-th program state and the j-th program state group.

The varying may include applying the program pulse having a sum of a base value and a group base offset value as a group initial value of the step size for the n-th program state within the j-th program state group; and adjusting the step size from the group initial value to a pre-updated value when, for the first time, one of the target memory cells has a higher threshold voltage than a pre-verification level for the n-th program state within the j-th program state group. The pre-updated value may be a sum of the base value and a group pre-offset value.

The varying may further include adjusting the step size from the pre-updated value to a main-updated value when, for the first time, one of the target memory cells has a higher threshold voltage than a main verification level for the n-th program state within the j-th program state group. The main-updated value may be a sum of the base value and a group main-offset value.

The varying may further include keeping the step size to the main-updated value until all the target memory cells pass the main verification level for the n-th program state within the j-th program state group.

The base value may be equal to or greater than the main-updated value. The main-updated value may be equal to or greater than the pre-updated value. The pre-updated value may be equal to or greater than the group initial value.

The j-th program state group may be a relatively lower program state group among J program state groups.

The base value may be equal to or less than the group initial value. The group initial value may be equal to or less than the pre-updated value. The pre-updated value is equal to or less than the main-updated value.

The j-th program state group may be a relatively higher program state group among J program state groups.

The varying may further include defining, as a first loop base value, the step size currently having one of the group initial value, pre-updated value and main-updated value at a moment when a number of advanced program loops exceeds a first threshold; and replacing the base value with a sum of the first loop base value and a negative first offset as a first updated base value, to continue performing the plural program loops with the first updated base value for the step size to have one of the first updated base value, a sum of the first loop base value and the pre-offset value as the pre-updated value and a sum of the first loop base value and the main-offset value as the main-updated value.

The varying may further include defining, as a second loop base value, the step size currently having one of the first updated base value, pre-updated value and main-updated value at a moment when the number of advanced program loops exceeds a second threshold greater than the first threshold; and replacing the first loop base value with a sum of the second loop base value and a negative second offset as a second updated base value, to continue performing the plural program loops with the second updated base value for the step size to have one of the second updated base value, a sum of the second loop base value and the pre-offset value as the pre-updated value and a sum of the second loop base value and the main-offset value as the main-updated value. An absolute value of the second offset is greater than an absolute value of the first offset.

Additional embodiments of the present disclosure will become apparent from the following description.

### BRIEF DESCRIPTION OF THE DRAWINGS

FIG. 1 is a block diagram illustrating a storage system.

FIG. 2 is a diagram illustrating the structure of storage device.

FIG. 3 is a diagram illustrating a memory cell array.

FIG. 4 is a diagram illustrating a program operation according to a double verify program (DPGM) scheme.

FIG. 5 is a flowchart illustrating a program operation according to the DPGM scheme.

FIG. 6 is a diagram illustrating a program operation according to a program loop scheme.

FIG. 7 is a diagram illustrating program loops each including program pulse application process and verification processes.

FIG. 8 is a diagram illustrating memory cells belonging to selected program states after programming all 32 program states of PLCs with a constant step size.

FIG. 9 illustrates a fixed incremental step pulse program (ISPP) slope with a varying step size as a relationship between a program pulse to be applied to memory cells and a target threshold voltage of the memory cells.

FIG. 10 illustrates the width of threshold voltage distribution when the step size is small under the situation of fixed ISPP slope.

FIG. 11 illustrates the width of threshold voltage distribution when the step size is great under the situation of fixed ISPP slope.

FIG. 12 illustrates a varying ISPP slope with a fixed step size as a relationship between a program pulse to be applied to memory cells and a target threshold voltage of the memory cells.

FIG. 13 illustrates the width of threshold voltage distribution when the ISPP slope is slow under the situation of fixed step size.

FIG. 14 illustrates the width of threshold voltage distribution when the ISPP slope is fast under the situation of fixed step size.

FIG. 15 schematically illustrates a threshold voltage distribution with indication of width and valley thereof.

FIG. 16 is a diagram illustrating program loops each including program pulse application process and verification process according to embodiment 1 of the present disclosure.

FIG. 17 is a flowchart illustrating a program operation according to embodiment 1 of the present disclosure.

FIG. 18 is a flowchart illustrating a program operation according to embodiment 2 of the present disclosure.

FIG. 19 is a flowchart illustrating a program operation according to embodiment 3 of the present disclosure.

FIG. 20 is a flowchart illustrating a program operation according to embodiment 4 of the present disclosure.

FIG. 21 shows a measured data supporting a read window improvement by the embodiments of the present disclosure.

### DETAILED DESCRIPTION

Various embodiments of the present disclosure are described below in more detail with reference to the accompanying drawings. The embodiments of the present disclosure may, however, be embodied in different forms and thus should not be construed as limited to the embodiments set forth herein. Rather, these embodiments are provided so that this disclosure conveys the scope of the present disclosure to those skilled in the art. Moreover, reference herein to “an embodiment,” “another embodiment,” or the like is not necessarily to only one embodiment, and different references to any such phrase are not necessarily to the same embodiment(s). The term “embodiments” as used herein does not necessarily refer to all embodiments. Throughout this disclosure, like reference numerals refer to like parts in the figures and embodiments of the present disclosure.

Embodiments of the present disclosure can be implemented in numerous ways, including as a process; an apparatus; a system; a computer program product embodied on a computer-readable storage medium; and/or a processor, such as a processor suitable for executing instructions stored on and/or provided by a memory coupled to the processor. In general, the order of the operations of disclosed processes may be altered within the scope of the present disclosure. Unless stated otherwise, a component such as a processor or a memory described as being suitable for performing a task may be implemented as a general device or circuit component that is configured or otherwise programmed to perform the task at a given time or as a specific device or circuit component that is manufactured to perform the task. As used herein, the term ‘processor’ or the like refers to one or more devices, circuits, and/or processing cores suitable for processing data, such as computer program instructions.

The methods, processes, and/or operations described herein may be performed by code or instructions to be executed by a computer, processor, controller, or other signal processing device. The computer, processor, controller, or other signal processing device may be those described herein or one in addition to the elements described herein. Because the algorithms that form the basis of the methods (or operations of the computer, processor, controller, or other signal processing device) are described herein, the code or instructions for implementing the operations of the method embodiments may transform the computer, processor, controller, or other signal processing device into a special-purpose processor for performing methods herein.

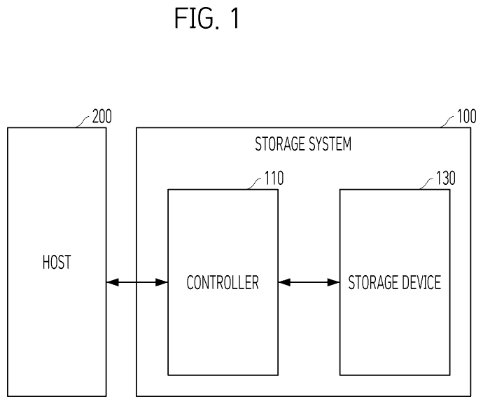

FIG. 1 is a block diagram illustrating a storage system 100.

Referring to FIG. 1, the storage system 100 may include a storage device 130 and a controller 110.

The storage system 100 may access data stored therein in response to a request from a host system 200. Examples of the host system 200 include a cellular phone, a smartphone, an MP3 player, a laptop computer, a desktop computer, a game player, a TV, a tablet PC, and an in-vehicle infotainment system.

The storage system 100 may be implemented as any of various types of storage systems. For example, the storage system 100 may be implemented as a solid state drive (SSD), a multimedia card in the form of a multimedia card (MMC), (e.g., an eMMC, an RS-MMC, or a micro-MMC), a secure digital card in the form of an SD (e.g., a mini-SD or a micro-SD), a universal serial bus (USB) storage device, a universal flash storage (UFS) device, a personal computer memory card international association (PCMCIA) card type storage device, a peripheral component interconnection (PCI) card type storage device, a PCI express (PCI-e) card type storage device, a compact flash (CF) card, a smart media card, or a memory stick.

The storage system 100 may be manufactured through any of various types of packages. For example, the storage system 100 may be manufactured through a package on package (POP), a system in package (SIP), a system on chip (SOC), a multi-chip package (MCP), a chip on board (COB), a wafer-level fabricated package (WFP), or a wafer-level stack package (WSP).

The storage device 130 may access data stored therein. The storage device 130 may operate in response to a command from the controller 110. The storage device 130 may include a memory cell array 210 including a plurality of memory cells configured to store data therein. The memory cell array may include a plurality of memory blocks. Each of the memory blocks may include pages, each of which includes memory cells. According to an embodiment, data may be stored in and readout from the storage device 130 in units of pages. Data may be erased or removed from the storage device 130 in units of blocks.

According to an embodiment, the storage device 130 may be any of Double Data Rate Synchronous Dynamic Random-Access Memory (DDR SDRAM), Low Power Double Data Rate4 (LPDDR4) SDRAM, Graphics Double Data Rate (GDDR) SDRAM, Low Power DDR (LPDDR), Rambus Dynamic Random Access Memory (RDRAM), NAND flash memory, Vertical NAND flash memory, NOR flash memory, resistive random-access memory (RRAM), phase-change random-access memory (PRAM), magneto-resistive random-access memory (MRAM), ferroelectric random-access memory (FRAM), spin-transfer torque random-access memory (STT-RAM) and so forth. By way of example, the storage device 130 can be a NAND flash memory in the context of the following description.

The storage device 130 may have a two-dimensional or three-dimensional array structure. The embodiments of the present disclosure may be applied not only to a flash memory device, in which a charge storage layer includes a conductive floating gate (FG), but also to a charge trap flash (CTF) memory device, in which a charge storage layer includes an insulating layer.

The storage device 130 may receive a command and an address from the controller 110. The storage device 130 may access, in response to the command, an area selected by the address within the memory cell array. For example, the storage device 130 may perform, in response to the command, various operations such as a write operation or a program operation, a read operation and an erase operation. For example, during the program operation, the storage device 130 may program data into the selected area. During the read operation, the storage device 130 may read data from the selected area. During the erase operation, the storage device 130 may erase or remove data from the selected area.

The controller 110 may control the operation of the memory device 50.

When a power voltage is applied to the storage system 100, the controller 110 may execute firmware such as a Flash Translation Layer (FTL) for controlling communication between the host system 200 and the storage device 130.

According to an embodiment, the controller 110 may receive data and a logical address from the host system 200 and include firmware (not shown) that translates the logical address into a physical address. A logical address may be identified by the host system 200 and may indicate a logical location within the storage device 130. A physical address may indicate an actual location within the storage device 130. The controller 110 may manage, in an operational memory, a logical-to-physical map table representing a mapping relationship between the logical address and the physical address.

In response to a request from the host system 200, the controller 110 may control the storage device 130 to perform an operation. For example, in response to a program request from the host system 200, the controller 110 may provide a program command, a physical address and data to the storage device 130. In response to a read request provided together with a logical address from the host system 200, the controller 110 may provide the storage device 130 with the read command and a physical address corresponding to the logical address. In response to an erase request provided together with a logical address from the host system 200, the controller 110 may provide the storage device 130 with an erase command and a physical address corresponding to the logical address.

Without a request from the host system 200, the controller 110 may control the storage device 130 to perform a background operation such as a program operation for wear leveling or for garbage collection.

According to an embodiment, the storage system 100 may further include an operational memory (not shown). The controller 110 may control data exchange between the host system 200 and the operational memory. The controller 110 may temporarily store, in the operational memory, system data for controlling the storage device 130. For example, the controller 110 may temporarily store, in the operational memory, data from the host system 200 and transfer the temporarily stored data to the storage device 130.

As a buffer memory, the operational memory may store codes or commands executed by the controller 110. As a cache memory, the operational memory may store data processed by the controller 110.

According to an embodiment, the operational memory may be any of DRAM such as DDR SDRAM, LPDDR4 SDRAM, GDDR SDRAM, LPDDR or RDRAM, SRAM and so forth.

The host system 200 may communicate with the storage system 100 through at least one of various communication interfaces or standards such as a Universal Serial Bus (USB), Serial AT Attachment (SATA), a Serial Attached SCSI (SAS), a High Speed Interchip (HSIC), a Small Computer System Interface (SCSI), a Peripheral Component Interconnection (PCI), PCI express (PCIe), NonVolatile Memory express (NVMe), Universal Flash Storage (UFS), Secure Digital (SD), a Multi-Media Card (MMC), an embedded MMC (eMMC), a Dual In-line Memory Module (DIMM), a Registered DIMM (RDIMM), a Load Reduced DIMM (LRDIMM) and so forth.

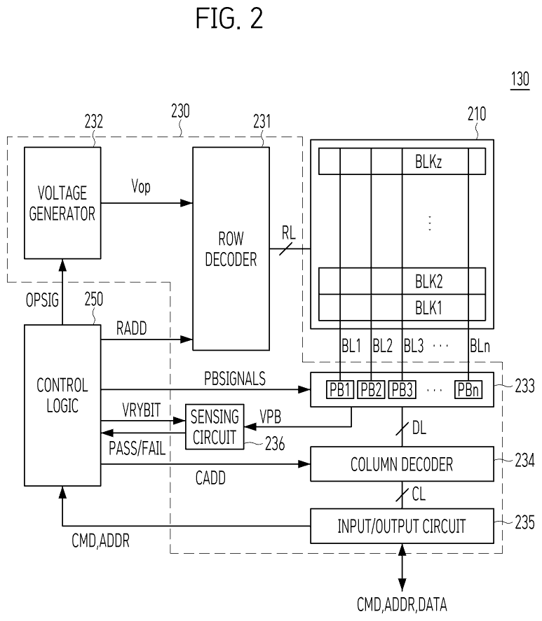

FIG. 2 is a diagram illustrating a structure of the storage device 130.

Referring to FIG. 2, the storage device 130 may include the memory cell array 210, an operating circuit 230 and a control logic 250. The operating circuit 230 and control logic 250 may be collectively referred to as a control circuit.

The memory cell array 210 may include a plurality of memory blocks BLK1 to BLKz coupled to a row decoder 231 through row lines RL, each configured by at least one source select line, a plurality of word lines, and at least one drain select line. The plurality of memory blocks BLK1 to BLKz may be coupled to a page buffer group 233 through bit lines BL1 to BLn. Each of the plurality of memory blocks BLK1 to BLKz may include a plurality of pages. A page may be defined as a group of memory cells coupled to a single word line. The plurality of memory cells may be nonvolatile.

According to an embodiment, the memory cell array 210 may include any of a single-level cell (SLC), a multi-level cell (MLC), a triple-level cell (TLC), a quadruple-level cell (QLC), and a further-higher-level cell, which will not limit the scope of the present disclosure.

The operating circuit 230 may be operable under the control of the control logic 250. The operating circuit 230 may perform an operation on a selected area within the memory cell array 210. The operating circuit 230 may drive the memory cell array 210. For example, the operating circuit 230 may apply various operating voltages to the row lines RL and the bit lines BL1 to BLn or discharge the applied voltages.

The operating circuit 230 may include the row decoder 231, a voltage generator 232, the page buffer group 233, a column decoder 234, an input/output circuit 235 and a sensing circuit 236.

The row decoder 231 may be coupled to the memory cell array 210 through the row lines RL. Within the row lines RL, the word lines may include normal word lines and dummy word lines. The row lines RL may further include a pipe select line.

The row decoder 231 may decode a row address RADD from the control logic 250. The row decoder 231 may select, according to the decoded address, at least one from the memory blocks BLK1 to BLKz. The row decoder 231 may select, according to the decoded address, at least one from the word lines coupled to the selected memory block to apply a voltage Vop from the voltage generator 232 to the selected word line.

For example, during a program pulse application process, the row decoder 231 may apply a program voltage to the selected word line and a program pass voltage to unselected word lines. During a verification process, the row decoder 231 may apply a verification voltage to the selected word line and a verification pass voltage to the unselected word lines. During a read operation, the row decoder 231 may apply a read voltage to the selected word line and a read pass voltage to the unselected word lines. During an erase operation, the row decoder 231 may select, according to the decoded address, one of the memory blocks BLK1 to BLKz and may apply a ground voltage to word lines coupled to the selected memory block.

The voltage generator 232 may operate under the control of the control logic 250. The voltage generator 232 may generate various operating voltages Vop through an external power voltage supplied to the storage device 130 or an internal power voltage regulated from the external power voltage. The voltage generator 232 may generate, in response to an operation signal OPSIG, the operating voltages Vop for program, read and erase operations. For example, the voltage generator 232 may generate a program voltage, a verification voltage, a pass voltage, a read voltage, and an erase voltage.

The page buffer group 233 may include first to n-th page buffers PB1 to PBn coupled to the memory cell array 210 through the respective first to n-th bit lines BL1 to BLn. The first to n-th page buffers PB1 to PBn may operate under the control of the control logic 250. The first to n-th page buffers PB1 to PBn may operate in response to page buffer control signals PBSIGNALS. The first to n-th page buffers PB1 to PBn may temporarily store therein data provided through the first to n-th bit lines BL1 to BLn or may sense voltages or currents of the bit lines BL1 to BLn during a read or verification process.

When a program voltage is applied to a selected word line during a program pulse application process, the first to n-th page buffers PB1 to PBn may transfer data from the column decoder 234 and the input/output circuit 235 to selected memory cells through the first to n-th bit lines BL1 to BLn. Memory cells of the selected page may be programmed according to the transferred data. During a verification process, the first to n-th page buffers PB1 to PBn may sense a voltage or a current from the first to n-th bit lines BL1 to BLn to read page data from the selected memory cells.

Under the control of the column decoder 234 during a read operation, the first to n-th page buffers PB1 to PBn may read the data from the memory cells of the selected page through the first to n-th bit lines BL1 to BLn and may output the read data to the input/output circuit 235.

During an erase operation, the first to n-th page buffers PB1 to PBn may float the first to n-th bit lines BL1 to BLn or may apply an erase voltage to the first to n-th bit lines BL1 to BLn.

The column decoder 234 may transfer data between the input/output circuit 235 and the page buffer group 233 according to a column address CADD. For example, the column decoder 234 may exchange data with the first to n-th page buffers PB1 to PBn through data lines DL and with the input/output circuit 235 through column lines CL.

The input/output circuit 235 may transfer a command CMD and an address ADDR from the controller 110 to the control logic 250 and may exchange the data with the column decoder 234.

During a read operation or a verification process, the sensing circuit 236 may generate a reference current according to an allowable bit VRYBIT. The sensing circuit 236 may compare a sensing voltage VPB from the page buffer group 233 with a reference voltage generated by the reference current. As the result of the comparison, the sensing circuit 236 may output a pass signal PASS or a fail signal FAIL.

In response to the command CMD and the address ADDR, the control logic 250 may control the operating circuit 230 through the operation signal OPSIG, the row address RADD, the page buffer control signals PBSIGNALS and the allowable bit VRYBIT. The control logic 250 may control a read operation on a selected memory block in response to a sub-block read command and an address. The control logic 250 may control an erase operation on a selected sub-block included in the selected memory block in response to a sub-block erase command and the address. The control logic 250 may determine whether a verification process passes or fails according to the pass or fail signal PASS or FAIL.

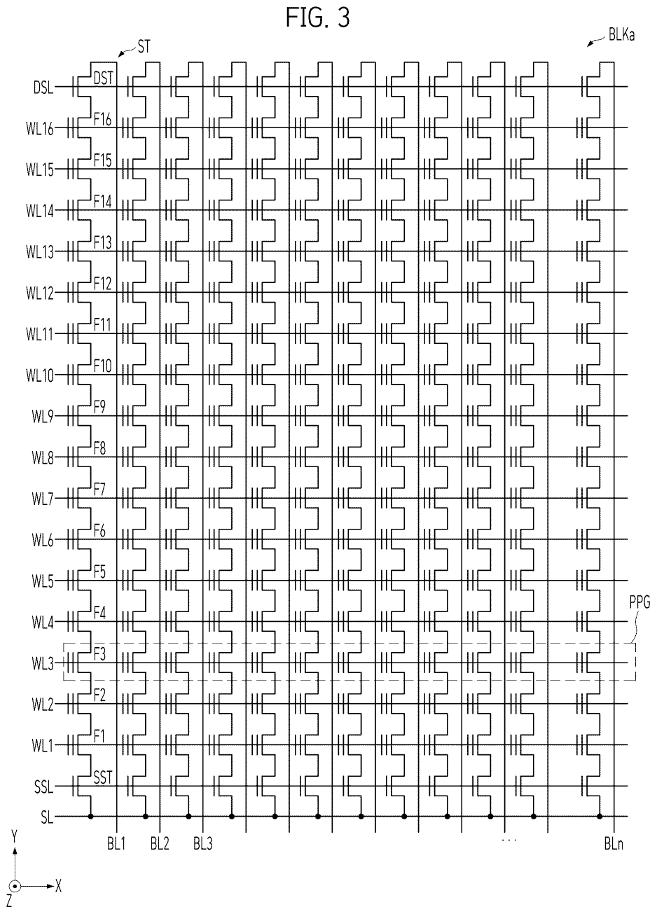

FIG. 3 is a diagram illustrating the memory cell array 210. FIG. 3 is a circuit diagram showing a representative memory block BLKa among the plurality of memory blocks BLK1 to BLKz in the memory cell array 210.

A first select line, word lines, and a second select line arranged in parallel with each other may be coupled to the memory block BLKa. The word lines may be arranged in parallel with each other between the first and second select lines. The first select line may be a source select line SSL and the second select line may be a drain select line DSL.

The memory block BLKa may include a plurality of strings coupled between the bit lines BL1 to BLn and a source line SL. The bit lines BL1 to BLn may be coupled to the respective strings and the strings may be commonly coupled to the source line SL. The strings may have the same configuration and a string ST coupled to the first bit line BL1 is described in detail as an example.

The string ST may include a source select transistor SST, a plurality of memory cells F1 to F16, and a drain select transistor DST coupled in series between the source line SL and the first bit line BL1. Although not illustrated, each string ST may include plural source select transistors SST, plural drain select transistors DST and more than the 16 memory cells F1 to F16.

A source of the source select transistor SST may be coupled to the source line SL and a drain of the drain select transistor DST may be coupled to the first bit line BL1. The memory cells F1 to F16 may be coupled in series between the source select transistor SST and the drain select transistor DST. Gates of the source select transistors SST included in different strings may be coupled to the source select line SSL. Gates of the drain select transistors DST included in the different strings may be coupled to the drain select line DSL. Gates of the memory cells F1 to F16 included in the different strings may be coupled to respective word lines WL1 to WL16. A group of memory cells coupled to the same word line among memory cells included in different strings may be referred to as a physical page PPG. The memory block BLKa may include as many physical pages PPG as the number of word lines WL1 to WL16.

The single physical page PPG including SLCs may store data of a single logical page LPG. The data of the single logical page LPG may include as many bits of data as the number of memory cells included in the single physical page PPG. The single physical page PPG including MLCs may store data of two or more logical pages LPG.

According to an embodiment, a memory block may have a three-dimensional structure. Each memory block may include a plurality of memory cells stacked over a substrate. The plurality of memory cells may be arranged in a +X direction, a +Y direction, and a +Z direction.

In an embodiment, the combination of the operating circuit 230 and the control logic 250 may be referred to as a control circuit. The control circuit may perform an operation on the memory cell array 210 as described herein. The control circuit may control the memory cell array 210 to perform an operation described herein.

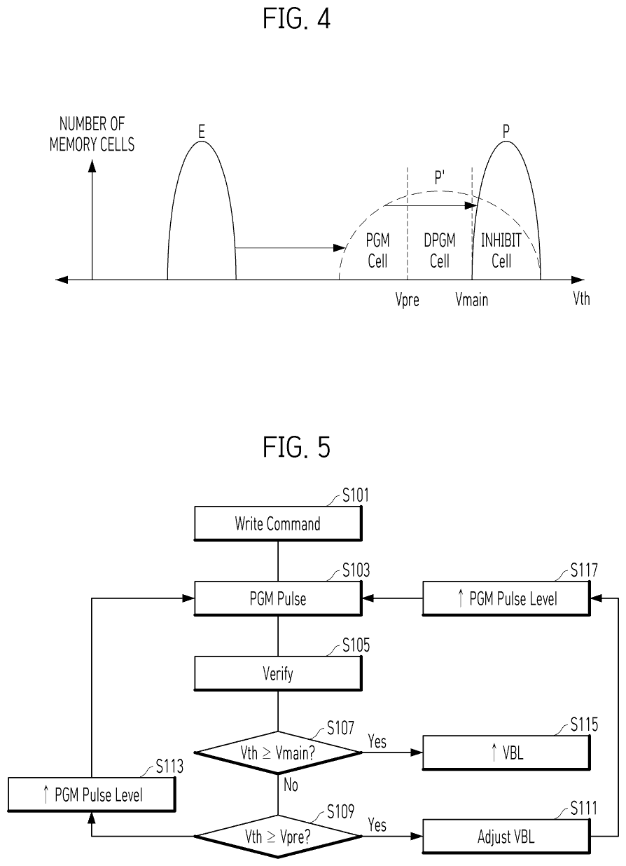

FIG. 4 is a diagram illustrating a program operation according to a double verify program (DPGM) scheme.

By way of example, FIG. 4 illustrates a process of programming memory cells from an erase state E to a program state P according to the DPGM scheme. In FIG. 4, a horizontal axis refers to a threshold voltage Vth of memory cells and a vertical axis refers to the number of memory cells. In FIG. 4, by way of example, the storage device 130 performs a program operation on a SLC.

Referring to FIG. 4, the memory cells in the erase state E may be programmed to the program state P as a target program state through the DPGM operation. The memory cells in the erase state E may be programmed to the program state P via a state P′.

According to an embodiment, the DPGM operation may include a program pulse application process and a verification process. The verification process may be performed with two verification voltage levels: a pre-verification voltage level Vpre and a main verification voltage level Vmain. The main verification voltage level Vmain may correspond to the target program state P. The pre-verification voltage level Vpre may be lower than the main verification voltage level Vmain.

The DPGM scheme may be used to achieve the tight threshold voltage distribution by identifying the memory cells whose threshold voltage below the main verification level Vmain, by performing additional pre-verification process on the memory cells and then by selectively soft-programming the memory cells, which have the threshold voltage falling between the pre-verification level Vpre and main verification level Vmain, through a non-zero bit line bias to improve the threshold voltage distribution corresponding to the target program state P.

The verification process may be performed twice: a first time according to the pre-verification voltage level Vpre (pre-verification process) and a second time according to the main verification voltage level Vmain (main verification process).

For example, after a program pulse is applied to the memory cells in the erase state E, the verification process may be performed with the pre-verification level Vpre and the main verification level Vmain. As a result of the verification process, the memory cells may be classified into three types of memory cells: first program permission memory cells (hereinafter, referred to as PGM memory cells), second program permission memory cells (hereinafter, referred to as DPGM memory cells) and program inhibition memory cells (hereinafter, referred to as INHIBIT memory cells). The PGM memory cells may have a threshold voltage lower than the pre-verification level Vpre. The DPGM memory cells may have a threshold voltage between the pre-verification level Vpre and main verification level Vmain. The INHIBIT memory cells may have a threshold voltage higher than the main verification level Vmain.

The INHIBIT memory cells may already belong to the target program state P and a program pulse need not be applied to gates of the INHIBIT memory cells any longer.

The PGM memory cells and the DPGM memory cells may not yet have reached the threshold voltages corresponding to the target program state P and the program pulse may be applied to the PGM memory cells and DPGM memory cells again through a subsequent program pulse application process.

In general, for a target program state, fast memory cells may first become the DPGM memory cells as the fast memory cells are programmed to first have threshold voltages between the pre-verification level Vpre and main verification level Vmain corresponding to the target program state P. Accordingly, during the subsequent program pulse application process, the DPGM memory cells may be soft-programmed by selectively applying the non-zero bit line bias to program the DPGM memory cells to have the pass threshold voltages corresponding to the target program state P, i.e., the threshold voltages equal to or higher than the main verification level Vmain. During the subsequent verification process after the soft-programming, the programmed memory cells may pass for the main verification level Vmain and may become the INHIBIT memory cells for all future program loops.

The PGM memory cells may be slow memory cells, on which a program operation is performed at a relatively low speed, whereas the DPGM memory cells may be fast memory cells, on which the program operation is performed at a relatively high speed. The speed of the program operation on the DPGM memory cells may be relatively high when compared with the speed of the program operation on the PGM memory cells. Therefore, in consideration of the speed of the program operation, the voltage level of the bit lines coupled to the DPGM memory cells may be set to the different level from the ground voltage GND level or the voltage level of the bit lines coupled to the PGM memory cells.

During a program operation, the voltage level of bit lines coupled to the DPGM memory cells may be set higher than the voltage level of bit lines coupled to the PGM memory cells. For example, the voltage level of the bit lines coupled to the PGM memory cells may be set to the ground voltage GND level and the voltage level of the bit lines coupled to the DPGM memory cells may be higher than the ground voltage GND level.

As the voltage level of the bit lines coupled to the PGM memory cells is set differently from the voltage level of the bit lines coupled to the DPGM memory cells, the threshold voltage distribution of the memory cells may become narrower.

FIG. 5 is a flowchart illustrating a program operation according to the DPGM scheme.

Referring to FIG. 5, the controller 110 may provide the storage device 130 with a write command to program data into one or more memory cells in operation S101. In operation S103, the storage device 130 may perform the program pulse application process of applying a program pulse to a selected word line. In operation S105, the storage device 130 may perform the verification process to determine whether a memory cell coupled to the selected word line has been properly programmed to the target program state P.

When the memory cell is determined as properly programmed to the target program state P in operation S107 as a result of the verification process of the operation S105, that is, when the memory cell is determined as the INHIBIT memory cell having the threshold voltage Vth higher than the main verification voltage level Vmain, the storage device 130 may raise, in operation S115, a voltage VBL to a program-inhibit level. The voltage VBL may be applied to a bit line coupled to the INHIBIT memory cell.

When the threshold voltage Vth of the memory cell is determined not yet to reach the main verification voltage level Vmain in the operation S107 but determined to reach the pre-verification voltage level Vpre in operation S109 as the result of the verification process of the operation S105, that is, when the memory cell is determined as the DPGM memory cell having the threshold voltage Vth between the pre-verification voltage level Vpre and main verification voltage level Vmain, the storage device 130 may adjust the voltage VBL in operation S111. As a result of the operation S111, the storage device 130 may set the voltage level of the bit lines coupled to the DPGM memory cell to a different level from the ground voltage GND level or the voltage level of the bit lines coupled to the PGM memory cell. In an embodiment, the voltage level of the bit line coupled to the DPGM memory cell may be higher than the ground voltage GND level or the voltage level of the bit lines coupled to the PGM memory cell.

After the operation S111, the storage device 130 may repeat the process from the operation S103 by increasing stepwise the level of the program pulse by an amount of step size in operation S117.

When the threshold voltage Vth of the memory cell is determined not yet to reach both the main verification voltage level Vmain and pre-verification voltage level Vpre in the operations S107 and S109 as the result of the verification process of the operation S105, that is, when the memory cell is determined as the PGM memory cell having the threshold voltage Vth lower than the pre-verification voltage level Vpre, the storage device 130 may repeat the process from the operation S103 by increasing stepwise the level of the program pulse by an amount of step size in operation S113.

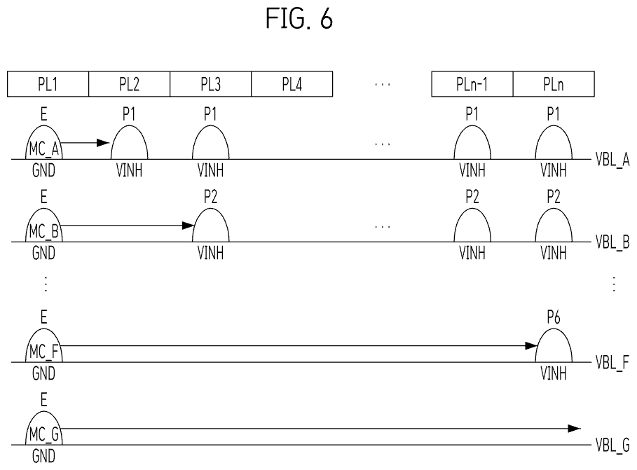

FIG. 6 is a diagram illustrating a program operation according to a program loop scheme.

Referring to FIG. 6, a plurality of program loops PL1 to PLn, where n is any suitable natural number of 2 or more, may be performed on selected memory cells during a program operation. A single program operation on a page may comprise the ‘n’ number of program loops PL1 to PLn at maximum. Each of the plurality of program loops PL1 to PLn may include the program pulse application process and the verification process. The verification process may be performed according to the pre-verification voltage level Vpre and the main verification voltage level Vmain.

In FIG. 6, by way of example, the memory cells are TLCs and programmed from the erase state E to one of first to seventh program states P1 to P7.

As an example, among the selected memory cells to which the program operation is performed, memory cells MC_A may be programmed to the first program state P1, memory cells MC_B to the second program state P2, memory cells MC_C to the third program state P3, memory cells MC_D to the fourth program state P4, memory cells MC_E to the fifth program state P5, memory cells MC_F to the sixth program state P6 and memory cells MC_G to the seventh program state P7. When the program operation is permitted, a voltage of a bit line coupled to each of memory cells MC_A to MC_F may be set to the ground voltage GND or a VM voltage, which is 1V as an example.

All memory cells MC_A are programmed to the first program state P1 in the first program loop PL1. Accordingly, a program operation on the memory cells MC_A may be inhibited from the second program loop PL2. Accordingly, from the second program loop PL2, a voltage level of a bit line VBL_A coupled to each of the memory cells MC_A may be set to the program inhibition voltage level VINH.

All memory cells MC_B are programmed to the second program state P2 in the second program loop PL2. Accordingly, a program operation on the memory cells MC_B may be inhibited from the third program loop PL3. Accordingly, from the third program loop PL3, a voltage level of a bit line VBL_B coupled to each of the memory cells MC_B may be set to the program inhibition voltage level VINH.

All memory cells MC_F are programmed to the sixth program state P6 in the (N−1)th program loop PLn−1. Accordingly, a program operation on the memory cells MC_F may be inhibited from the Nth program loop PLn. Accordingly, from the Nth program loop PLn, a voltage level of a bit line VBL_F coupled to each of the memory cells MC_F may be set to the program inhibition voltage level VINH. When all memory cells MC_G are programmed to the seventh program state P7 in the Nth program loop PLn, all memory cells MC_A to MC_F may be regarded as properly programmed and thus the program operation may then end.

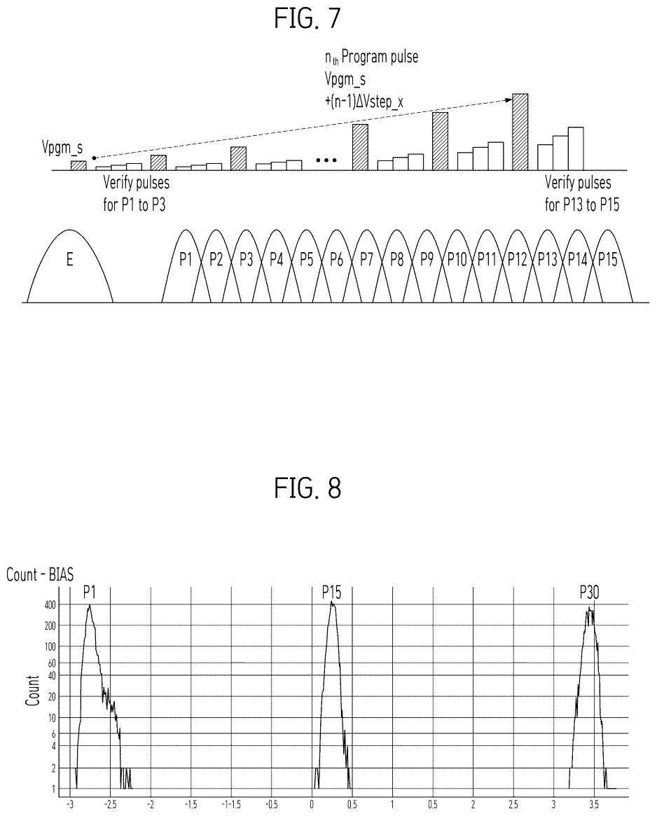

FIG. 7 is a diagram illustrating the program loops each including the program pulse application process and verification processes.

Referring to FIG. 7, program data may be loaded into the first to n-th page buffers PB1 to PBn connected to the bit-lines of the memory cell array 210. A single program pulse application process may be performed to apply a single program pulse to all memory cells except for the erased cells. The verification processes may immediately follow the single program pulse application process to determine whether a threshold voltage of each memory cell reaches a pass threshold voltage corresponding to a target program state. If the memory cell passes a corresponding pass threshold voltage level, the memory cell may become under the program-inhibition mode. By repeating the alternation of the program pulse application process and the verification processes, all memory cells may become programmed to corresponding program states or corresponding program levels.

Referring to FIG. 7, each time the program loop proceeds, the level of program pulse applied to the word line may increase by a step size Vstep_x compared to a program pulse in a previous program loop according to the incremental step pulse program (ISPP) scheme. Here, the step size may be predetermined. When all memory cells connected to the selected word line do not reach the target program state even though program loops are performed to a preset maximum number of times, it may be determined that the program operation has failed. The number of program states verified in each program loop may be at least two or more program states.

The control on tight threshold voltage distribution may be critical for better reliability of a memory cell, especially of the quadruple-level memory cell (QLC), the penta-level memory cell (PLC), or beyond. The conventional scheme of tuning bit line biasing is not enough for tightening the width of threshold voltage distribution for the QLC, PLC or beyond.

The width of threshold voltage distribution per program state is not uniform. The widths of the threshold voltage distribution highly depend on the levels of program states and the number of applied program pulses or the number of advanced program loops. In general, memory cells belonging to the relatively lower program states are more susceptible to disturbance or interference than the relatively higher program states, which results in the wider widths of threshold voltage distribution.

One possible solution for the susceptibility of memory cells belonging to the relatively lower program states would be to reduce the step size of program pulse. However, when the step size is too small, the number of program pulse application processes or the number of applied program pulses increases and therefore the disturbance of pass voltage can be caused. Conventionally, the step size is constant to all program states, which can cause over-program for the memory cells to belong to the relatively lower program states when the step size is too big and can cause the disturbance of pass voltage for the memory cells to belong to the relatively higher program states when the step size is too small.

Further, the width of threshold voltage distribution depends not only on the program state but also on the number of advanced program loops. As the number of advanced program loops becomes greater, the speed of program operation becomes faster and the width becomes wider due to the increased speed of the program operation. The great number of applied program pulses can cause the disturbance of pass voltage because the pass voltage steps up with the program pulse.

Embodiments of the present disclosure may provide a program scheme for 3D NAND to improve the budget of threshold voltage distribution by adjusting the step size based on a number of advanced program loops and/or a program state or a group of program states by changing the program bias or the bit line bias. To make the tighter width of threshold voltage distribution, the small step size may be applied for the relatively lower program states and the greater step size may be applied for the relatively higher program states, in order not to increase the number of applied program pulses to a greater number.

According to an embodiment, each program state may be mapped to a single step size for the tighter width of threshold voltage distribution. According to an embodiment, each group of program states may be mapped to a single step size for the tighter width of threshold voltage distribution.

According to an embodiment, as the number of advanced program loops becomes greater, the step size needs to be reduced to compensate for the wide width of threshold voltage distribution to make the tight width of threshold voltage distribution.

FIG. 8 is a diagram illustrating memory cells belonging to selected program states P1, P15 and P30 after programming all 32 program states E and P1 to P31 of PLCs with a constant step size.

Referring to FIG. 8, the widths of threshold voltage distributions are not uniform per program state. The memory cells belonging to the program state P1 may have been over-programmed. To make the tighter width of threshold voltage distribution representing the program state P1, a small step size may be applied. However, the small step size may cause the disturbance of pass voltage for PLCs belonging to the rest of the program states P2 to P31 due to the increased number of applied program pulses.

Once a memory cell has the pass threshold voltage corresponding to the target program state P, i.e., the threshold voltage equal to or higher than the main verification level Vmain corresponding to the target program state P, the memory cell may become the INHIBIT memory cell to be program-inhibited for the target program state P. The width of threshold voltage distribution may mainly depend on the ISPP slope and the step size of program pulse.

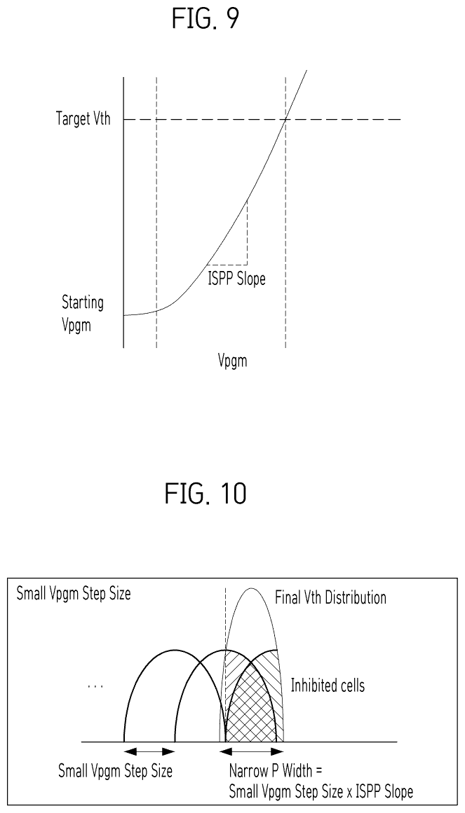

FIG. 9 illustrates a fixed ISPP slope with a varying step size as a relationship between a program pulse Vpgm to be applied to memory cells and a target threshold voltage Target Vth of the memory cells.

FIG. 10 illustrates the width of threshold voltage distribution when the step size is small under the situation of the fixed ISPP slope.

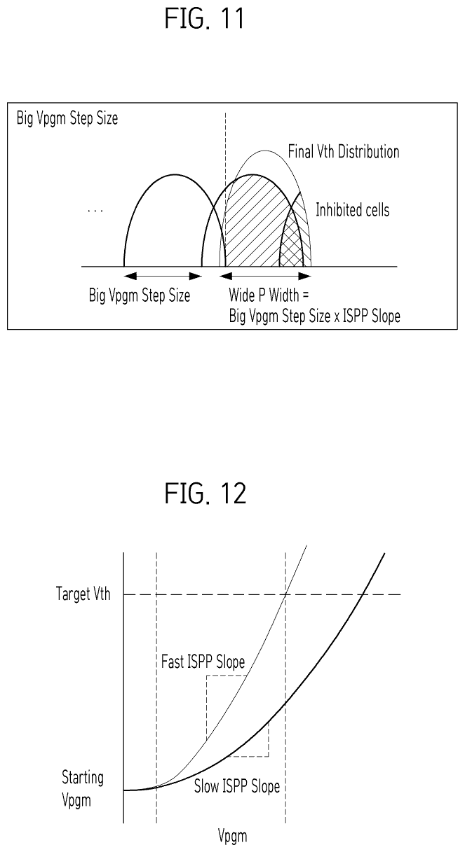

FIG. 11 illustrates the width of threshold voltage distribution when the step size is great under the situation of the fixed ISPP slope.

Referring to FIGS. 9 to 11, the width of threshold voltage distribution becomes tightened when the step size is small under the situation of the fixed ISPP slope.

FIG. 12 illustrates a varying ISPP slope with a fixed step size as a relationship between a program pulse Vpgm to be applied to memory cells and a target threshold voltage Target Vth of the memory cells.

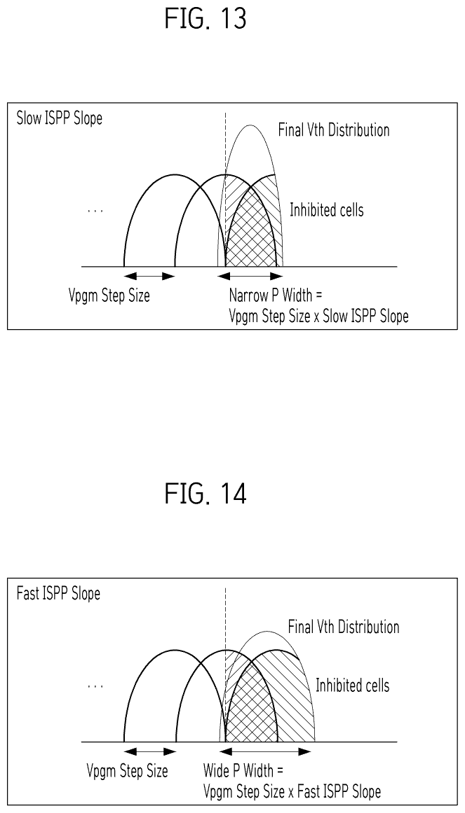

FIG. 13 illustrates the width of threshold voltage distribution when the ISPP slope is slow under the situation of the fixed step size.

FIG. 14 illustrates the width of threshold voltage distribution when the ISPP slope is fast under the situation of the fixed step size.

Referring to FIGS. 12 to 14, the width of threshold voltage distribution becomes tightened when the ISPP slope is slow under the situation of the fixed step size.

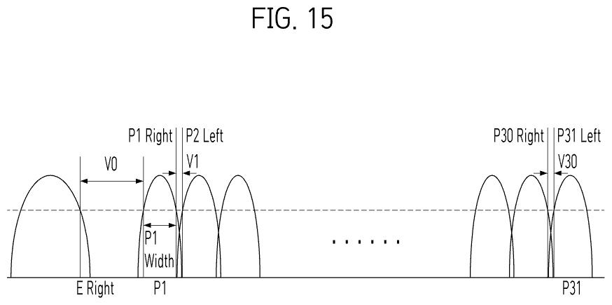

FIG. 15 schematically illustrates the threshold voltage distribution with indication of width and valley thereof.

Referring to FIG. 15, the width and valley of threshold voltage distribution affect the read window budget (RWB), which is mathematically represented as

$$RWB = {\sum }_{i = 0}^{i = n} [ Vi = ( Lower end of {P}_{i + 1} ) - ( Higher end of {P}_{i} ) ] ,$$

where Vᵢ represents the valley between the program states Pᵢ₊₁ and Pᵢ.

### Embodiment 1

According to embodiment 1 of the present disclosure, a step size STSZ of program pulse may vary based on a program state.

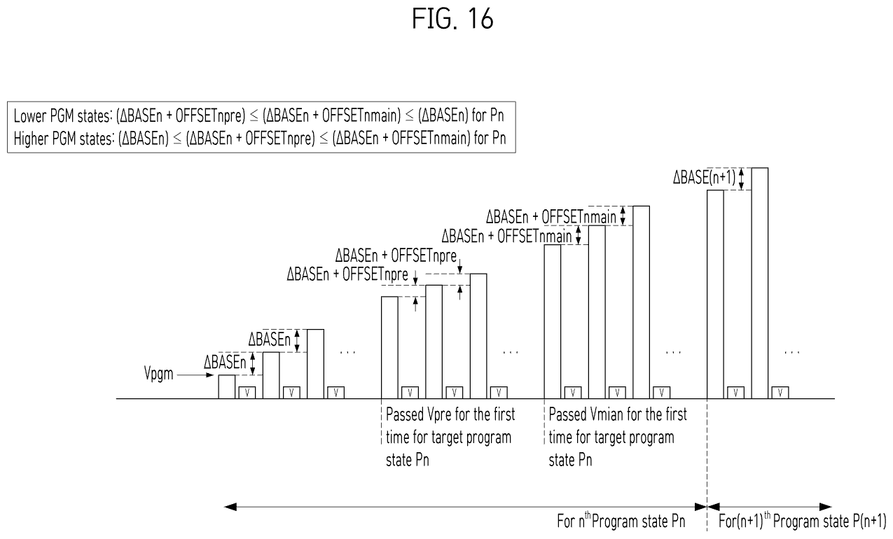

FIG. 16 is a diagram illustrating the program loops each including the program pulse application process and verification process according to the embodiment 1 of the present disclosure. FIG. 16 schematically shows the program operation of performing the program loops according to the DPGM scheme.

Referring FIG. 16, the step size STSZ of a program pulse Vpgm for a target program state Pn may have a base value ΔBASEn as an initial value.

When a memory cell has a higher threshold voltage than the pre-verification level Vpre for the target program state Pn with the step size STSZ of the base value ΔBASEn for the first time but all memory cells do not yet have a higher threshold voltage than the pre-verification level Vpre for the target program state Pn, the step size STSZ for the target program state Pn may be adjusted to a pre-updated value ‘ΔBASEn+OFFSETnpre’, which can prevent the over-program. The offset value OFFSETnpre may be referred to as a pre-offset value.

When a memory cell has a higher threshold voltage than the main verification level Vmain for the target program state Pn with the step size STSZ of the pre-updated value ‘ΔBASEn+OFFSETnpre’ for the first time, the step size STSZ for the target program state Pn may be further adjusted to the main-updated value ‘ΔBASEn+OFFSETnmain’, which can prevent a big jump of the step size STSZ to an initial value ΔBASE(n+1) for the next target program state P(n+1). The offset value OFFSETnmain may be referred to as a main-offset value. The initial values ΔBASEn and ΔBASE(n+1) respectively for adjacent program states Pn and P(n+1) may be the same as each other or different from each other according to an embodiment. Here, the natural number ‘n’ may be greater than 1 and less than ‘N’ representing a total number of program states, to which target memory cells are supposed to belong through the program operation. For example, ‘N’ may be 15 for the QLC or 31 for the PLC.

When the target program state Pn is a lower one among plural program states, to which target memory cells are supposed to belong through the program operation, the offset value OFFSETnpre for the target program state Pn may be negative and therefore the pre-updated value ‘ΔBASEn+OFFSETnpre’ may be less than the base value ΔBASEn for the target program state Pn.

When the target program state Pn is a lower one among plural program states, to which target memory cells are supposed to belong through the program operation, the offset value OFFSETnmain for the target program state Pn may be negative and therefore the main-updated value ‘ΔBASEn+OFFSETnmain’ may be less than the base value ΔBASEn for the target program state Pn.

When the target program state Pn is a lower one among plural program states, to which target memory cells are supposed to belong through the program operation, the main-updated value ‘ΔBASEn+OFFSETnmain’ may be greater than the pre-updated value ‘ΔBASEn+OFFSETnpre’ or the absolute value of the main-updated value ‘ΔBASEn+OFFSETnmain’ may be less than the pre-updated value ‘ΔBASEn+OFFSETnpre’.

That is, for each of the relatively lower program states Pn, the offset values OFFSETnpre and OFFSETnmain may be negative for the relatively lower program state Pn, which results in the relationship: (ΔBASEn+OFFSETnpre)≤A (BASEn+OFFSETnmain)≤ΔBASEn.

The negative offset values OFFSETnpre and OFFSETnmain for the relatively lower program states may make each of the pre-updated value ‘ΔBASEn+OFFSETnpre’ and the main-updated value ‘ΔBASEn+OFFSETnmain’ less than the base value ΔBASEn for the relatively lower program states, which may prevent the over-program of the memory cells, which are supposed to belong to the relatively lower program states through the program operation, and therefore may improve the read window budget by tightening the width of threshold voltage distribution.

When the target program state Pn is a higher one among plural program states, to which target memory cells are supposed to belong through the program operation, the offset value OFFSETnpre for the target program state Pn may be positive and therefore the pre-updated value ‘ΔBASEn+OFFSETnpre’ may be greater than the base value ΔBASEn for the target program state Pn.

When the target program state Pn is a higher one among plural program states, to which target memory cells are supposed to belong through the program operation, the offset value OFFSETnmain for the target program state Pn may be positive and therefore the main-updated value ‘ΔBASEn+OFFSETnmain’ may be greater than the base value ΔBASEn for the target program state Pn.

When the target program state Pn is a higher one among plural program states, to which target memory cells are supposed to belong through the program operation, the main-updated value ‘ΔBASEn+OFFSETnmain’ may be greater than the pre-updated value ‘ΔBASEn+OFFSETnpre’.

That is, for each of the relatively higher program states Pn, the offset values OFFSETnpre and OFFSETnmain may be positive for the relatively higher program state Pn, which results in the relationship: ΔBASEn≤(ΔBASEn+OFFSETnpre)≤(ΔBASEn+OFFSETnmain).

The positive offset values OFFSETnpre and OFFSETnmain for the relatively higher program states may make each of the pre-updated value ‘ΔBASEn+OFFSETnpre’ and the main-updated value ‘ΔBASEn+OFFSETnmain’ greater than the base value ΔBASEn for the relatively higher program states, which can prevent a big jump of the step size STSZ to an initial value ΔBASE(n+1) for the next target program state P(n+1). The initial values ΔBASEn and ΔBASE(n+1) respectively for adjacent program states Pn and P(n+1) may be the same as each other or different from each other according to an embodiment.

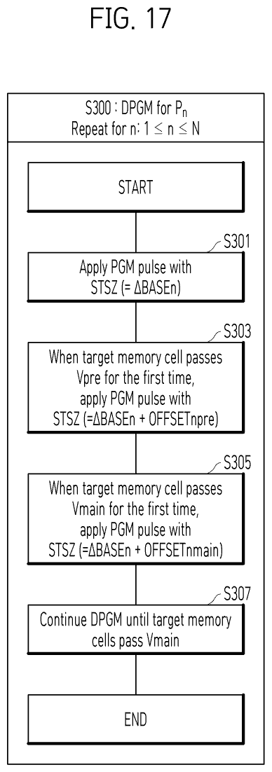

FIG. 17 is a flowchart illustrating the program operation according to the embodiment 1 of the present disclosure. FIG. 17 shows the program operation of performing the program loops according to the DPGM scheme.

Referring to FIG. 17, the control circuit of the storage device 130 may perform the program operation on target memory cells for the target program state Pn.

Referring to FIGS. 16 and 17, at operation S301, the control circuit may start the program operation for the target program state Pn by applying, to the target memory cells, a program pulse with the step size STSZ of the base value ΔBASEn as an initial value.

At operation S303, when a target memory cell becomes to have a higher threshold voltage than the pre-verification level Vpre for the target program state Pn for the first time but all target memory cells do not yet have a higher threshold voltage than the pre-verification level Vpre for the target program state Pn, the control circuit may adjust the step size STSZ for the target program state Pn to the pre-updated value ‘ΔBASEn+OFFSETnpre’ to apply, to the target memory cells, the program pulse with the step size STSZ of the pre-updated value ‘ΔBASEn+OFFSETnpre’.

At operation S305, when a target memory cell becomes to have a higher threshold voltage than the main verification level Vmain for the target program state Pn with the step size STSZ of the pre-updated value ‘ΔBASEn+OFFSETnpre’ for the first time, the control circuit may further adjust the step size STSZ to the main-updated value ‘ΔBASEn+OFFSETnmain’ to apply, to the target memory cells, the program pulse with the step size STSZ of the main updated value ‘ΔBASEn+OFFSETnmain’.

At operation S307, the control circuit may continue the program operation according to the DPGM scheme until the target memory cells become to have a higher threshold voltage than the main verification level Vmain for the target program state Pn with the step size STSZ of the main updated value ‘ΔBASEn+OFFSETnmain’.

The control circuit may repeat the operation S300 including the operations S301 to S307 for each of an N number of program states. Here, the natural number ‘n’ may be greater than 1 and less than ‘N’ representing a total number of program states, to which target memory cells are supposed to belong through the program operation. For example, ‘N’ may be 15 for the QLC or 31 for the PLC.

As disclosed above, the offset values OFFSETnpre and OFFSETnmain may be negative for the relatively lower program state Pn, which results in the relationship: (ΔBASEn+OFFSETnpre)≤(ΔBASEn+OFFSETnmain)≤ΔBASEn. Further, the offset values OFFSETnpre and OFFSETnmain may be positive for the relatively higher program state Pn, which results in the relationship: ΔBASEn≤(ΔBASEn+OFFSETnpre)≤(ΔBASEn+OFFSETnmain).

Because the offset values OFFSETnpre and OFFSETnmain may be negative for the relatively lower program states to reduce the step size STSZ but may be positive for the relatively higher program states to increase the step size STSZ, the ISPP scheme applied for the relatively lower program states may have the lower ISPP slope, which allows a larger step size STSZ for the relatively higher program states. This larger step size STSZ may reduce the number of applied program pulses, disturbs and the amount of program time. Thanks to this flexibility, the RWB may be improved without sacrificing the amount of program time.

### Embodiment 2

According to embodiment 2 of the present disclosure, a step size STSZ of program pulse may vary based on a group of program states.

According to the embodiment 2 of the present disclosure, an Ntot number of total program states may be grouped into a J number of groups PG1 to PGJ each including an Nj number of program states. Here, the natural number ‘n’ may be greater than 1 and less than ‘Nj’. The number ‘Ntot’ may represent the total number of program states, to which target memory cells are supposed to belong through the program operation. For example, ‘Ntot’ may be 15 for the QLC or 31 for the PLC.

According to the embodiment 2 of the present disclosure, the step size STSZ may be small for each of relatively lower program state groups, may be medium for each of middle program state groups and may be greater for each of relatively higher program state groups.

The step size STSZ of a program pulse Vpgm for a target program state Pn may have a base value ΔBASEn.

For the j-th group PGj among the groups PG1 to PGJ, the step size STSZ has a group initial value ‘ΔBASEn+OFFSETjbase’. The offset value OFFSETjbase may be referred to as a group base offset value. The offset value OFFSETjbase may make the step size STSZ smaller for each of the relatively lower program state groups, medium for each of the middle program state groups and greater for each of the relatively higher program state groups.

When a memory cell has a higher threshold voltage than the pre-verification level Vpre for the target program state Pn within the j-th group PGj with the step size STSZ of the group initial value ‘ΔBASEn+OFFSETjbase’ for the first time but all memory cells do not yet have a higher threshold voltage than the pre-verification level Vpre for the target program state Pn within the j-th group PGj, the step size STSZ for the target program state Pn within the j-th group PGj may be adjusted to a pre-updated value ‘ΔBASEn+OFFSETjpre’, which can prevent the over-program. The offset value OFFSETjpre may be referred to as a group pre-offset value.

When a memory cell has a higher threshold voltage than the main verification level Vmain for the target program state Pn within the j-th group PGj with the step size STSZ of the pre-updated value ‘ΔBASEn+OFFSETjpre’ for the first time, the step size STSZ for the target program state Pn within the j-th group PGj may be further adjusted to the main-updated value ‘ΔBASEn+OFFSETjmain’. The offset value OFFSETjmain may be referred to as a group main-offset value.

The offset values OFFSETjbase, OFFSETjpre and OFFSETjmain may be negative for the lower groups and positive for the higher groups among the groups PG1 to PGJ.

For the lower groups PGj among the groups PG1 to PGJ, the offset values OFFSETjbase, OFFSETjpre and OFFSETjmain may be negative, which results in the relationship: (ΔBASEn+OFFSETjbase)≤(ΔBASEn+OFFSETjpre)≤(ΔBASEn+OFFSETjmain)≤ΔBASEn.

For the higher groups PGj among the groups PG1 to PGJ, the offset values OFFSETjbase, OFFSETjpre and OFFSETjmain may be positive, which results in the relationship: ΔBASEn≤(ΔBASEn+OFFSETjbase)≤(ΔBASEn+OFFSETjpre)≤(ΔBASEn+OFFSETjmain).

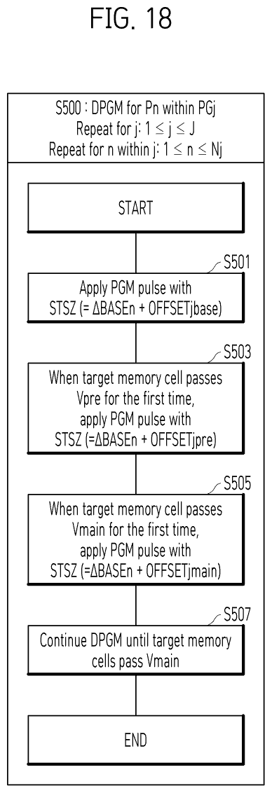

FIG. 18 is a flowchart illustrating the program operation according to the embodiment 2 of the present disclosure. FIG. 18 shows the program operation of performing the program loops according to the DPGM scheme.

According to the embodiment 2 of the present disclosure, the Ntot number of total program states may be grouped into the J number of groups PG1 to PGJ each including the Nj number of program states. Here, the natural number ‘n’ may be greater than 1 and less than ‘Nj’. For example, the number ‘Ntot’ may be 15 for the QLC or 31 for the PLC.

Referring to FIG. 18, the control circuit of the storage device 130 may perform the program operation on target memory cells for the target program state Pn within the j-th group PGj.

At operation S501, the control circuit may start the program operation for the target program state Pn within the j-th group PGj by applying, to the target memory cells, a program pulse with the step size STSZ of the group initial value ‘ΔBASEn+OFFSETjbase’, where ΔBASEn being the base value for the target program state Pn.

At operation S503, when a target memory cell becomes to have a higher threshold voltage than the pre-verification level Vpre for the target program state Pn within the j-th group PGj with the step size STSZ of the group initial value ‘ΔBASEn+OFFSETjbase’ for the first time but all target memory cells do not yet have a higher threshold voltage than the pre-verification level Vpre for the target program state Pn within the j-th group PGj, the control circuit may adjust the step size STSZ for the target program state Pn within the j-th group PGj to the pre-updated value ‘ΔBASEn+OFFSETjpre’ to apply, to the target memory cells, the program pulse with the step size STSZ of the pre-updated value ‘ΔBASEn+OFFSETjpre’.

At operation S505, when a target memory cell becomes to have a higher threshold voltage than the main verification level Vmain for the target program state Pn within the j-th group PGj with the step size STSZ of the pre-updated value ‘ΔBASEn+OFFSETjpre’ for the first time, the control circuit may further adjust the step size STSZ for the target program state Pn within the j-th group PGj to the main-updated value ‘ΔBASEn+OFFSETjmain’ to apply, to the target memory cells, the program pulse with the step size STSZ of the main-updated value ‘ΔBASEn+OFFSETjmain’.

At operation S507, the control circuit may continue the program operation according to the DPGM scheme until the target memory cells become to have a higher threshold voltage than the main verification level Vmain for the target program state Pn within the j-th group PGj with the step size STSZ of the main-updated value ‘ΔBASEn+OFFSETjmain’.

For each of the groups, the control circuit may repeat operation S500 including the operations S501 to S507 for each of the program states within each group. For example, the Ntot number of total program states may be grouped into the J number of groups PG1 to PGJ each including the Nj number of program states. The natural number ‘n’ may be greater than 1 and less than ‘Nj’. For example, the number ‘Ntot’ may be 15 for the QLC or 31 for the PLC.

As disclosed above, for the lower groups PGj among the groups PG1 to PGJ, the offset values OFFSETjbase, OFFSETjpre and OFFSETjmain may be negative, which results in the relationship: (ΔBASEn+OFFSETjbase)≤(ΔBASEn+OFFSETjpre)≤(ΔBASEn+OFFSETjmain)≤ΔBASEn. Further, for the higher groups PGj among the groups PG1 to PGJ, the offset values OFFSETjbase, OFFSETjpre and OFFSETjmain may be positive, which results in the relationship: ΔBASEn≤(ΔBASEn+OFFSETjbase)≤(ΔBASEn+OFFSETjpre)≤(ΔBASEn+OFFSETjmain).

### Embodiment 3

According to embodiment 3 of the present disclosure, a step size STSZ of program pulse may vary based on a program state and a number of advanced program loops.

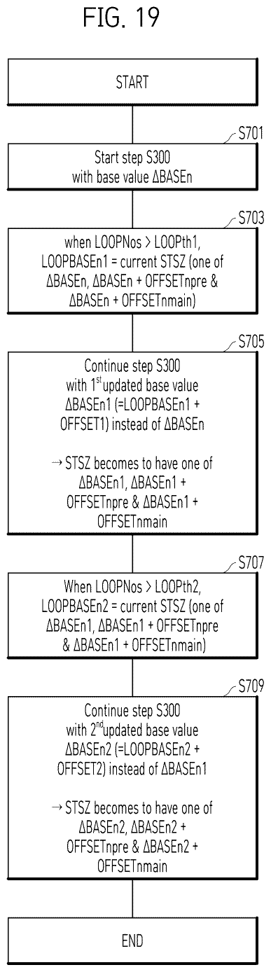

FIG. 19 is a flowchart illustrating the program operation according to the embodiment 3 of the present disclosure. FIG. 19 shows the program operation of performing the program loops according to the DPGM scheme.

According to the embodiment 3 of the present disclosure, first and second thresholds LOOPth1 and LOOPth2 may be defined for the number of advanced program loops LOOPNos. For example, the first and second thresholds LOOPth1 and LOOPth2 may be respectively 300, 500, etc.

At operation S701, the control circuit of the storage device 130 may start operation S300 of the embodiment 1, as disclosed with reference to FIGS. 16 and 17.

At operation S703, at the moment when the number of advanced program loops LOOPNos exceeds the first threshold LOOPth1 while performing the operation S300 of the embodiment 1, the control circuit may define, as a first loop base value LOOPBASEn1, the current step size STSZ having one of the initial value ΔBASEn, pre-updated value ‘ΔBASEn+OFFSETnpre’ and main-updated value ‘ΔBASEn+OFFSETnmain’.

At operation S705, the control circuit may continue step S300 of embodiment 1 from now on with a first updated base value ΔBASEn1 having a value of ‘LOOPBASEn1+OFFSET1’, the first offset OFFSET1 being negative. From now on, the operation S300 of embodiment 1 may be continued with the first updated base value ΔBASEn1 having the value of ‘LOOPBASEn1+OFFSET1’, the step size STSZ may have one of the first updated base value ΔBASEn1, pre-updated value ‘ΔBASEn1+OFFSETnpre’ and main-updated value ‘ΔBASEn1+OFFSETnmain’.

At operation S707, at the moment when the number of advanced program loops LOOPNos exceeds the second threshold LOOPth2 while continuing the operation S300 of the embodiment 1 according to the operation S705, the control circuit may define, as a second loop base value LOOPBASEn2, the current step size STSZ having one of the base value ΔBASEn1, pre-updated value ‘ΔBASEn1+OFFSETnpre’ and main-updated value ‘ΔBASEn1+OFFSETnmain’.

At operation S709, the control circuit may continue step S300 of embodiment 1 from now on with a second updated base value ΔBASEn2 having a value of ‘LOOPBASEn2+OFFSET2’, the second OFFSET2 being negative. From now on, the operation S300 of embodiment 1 may be continued with the second updated base value ΔBASEn2 having the value of ‘LOOPBASEn2+OFFSET2’, the step size STSZ may have one of the second updated base value ΔBASEn2, pre-updated value ‘ΔBASEn2+OFFSETnpre’ and main-updated value ‘ΔBASEn2+OFFSETnmain’.

The absolute value of the second offset OFFSET2 may be greater than the absolute value of the first offset OFFSET1.

### Embodiment 4

According to embodiment 4 of the present disclosure, a step size STSZ of program pulse may vary based on a group of program states and a number of advanced program loops.

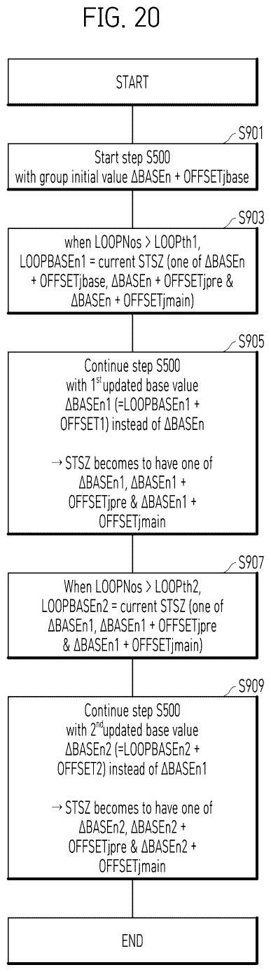

FIG. 20 is a flowchart illustrating the program operation according to the embodiment 4 of the present disclosure. FIG. 20 shows the program operation of performing the program loops according to the DPGM scheme.

According to the embodiment 4 of the present disclosure, first and second thresholds LOOPth1 and LOOPth2 may be defined for the number of advanced program loops LOOPNos. For example, the first and second thresholds LOOPth1 and LOOPth2 may be respectively 300, 500, etc.

At operation S901, the control circuit of the storage device 130 may start the operation S500 of the embodiment 2, as disclosed with reference to FIG. 18.

At operation S903, at the moment when the number of advanced program loops LOOPNos exceeds the first threshold LOOPth1 while performing the operation S500 of the embodiment 2, the control circuit may define, as a first loop base value LOOPBASEn1, the current step size STSZ having one of the group initial value ‘ΔBASEn+OFFSETjbase’, pre-updated value ‘ΔBASEn+OFFSETjpre’ and main-updated value ‘ΔBASEn+OFFSETjmain’.

At operation S905, the control circuit may continue the operation S500 of embodiment 2 from now on with a first updated base value ΔBASEn1 having a value of ‘LOOPBASEn1+OFFSET1’, the first offset OFFSET1 being negative. From now on, the operation S500 of embodiment 2 may be continued with the first updated base value ΔBASEn1 having the value of ‘LOOPBASEn1+OFFSET1’, the step size STSZ may have one of the first updated base value ΔBASEn1, pre-updated value ‘ΔBASEn1+OFFSETjpre’ and main-updated value ‘ΔBASEn1+OFFSETjmain’.

At operation S907, at the moment when the number of advanced program loops LOOPNos exceeds the second threshold LOOPth2 while continuing the operation S500 of the embodiment 2 according to the operation S905, the control circuit may define, as a second loop base value LOOPBASEn2, the current step size STSZ having one of the base value ΔBASEn1, pre-updated value ‘ΔBASEn1+OFFSETjpre’ and main-updated value ‘ΔBASEn1+OFFSETjmain’.

At operation S909, the control circuit may continue the operation S500 of embodiment 2 from now on with a second updated base value ΔBASEn2 having a value of ‘LOOPBASEn2+OFFSET2’, the second OFFSET2 being negative. From now on, the operation S500 of embodiment 2 may be continued with the second updated base value ΔBASEn2 having the value of ‘LOOPBASEn2+OFFSET2’, the step size STSZ may have one of the second updated base value ΔBASEn2, pre-updated value ‘ΔBASEn2+OFFSETjpre’ and main-updated value ‘ΔBASEn2+OFFSETjmain’.

The absolute value of the second offset OFFSET2 may be greater than the absolute value of the first offset OFFSET1.

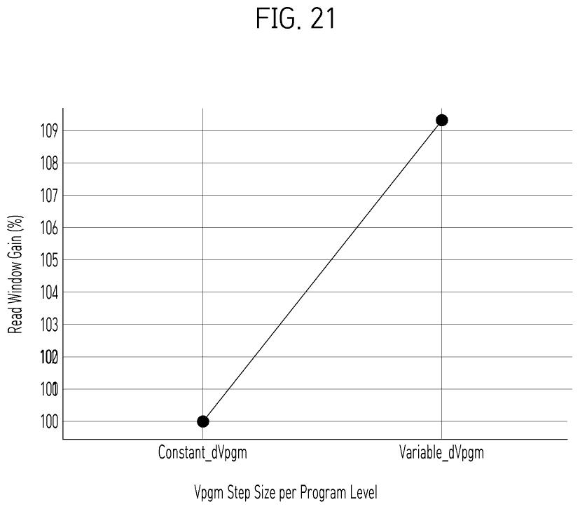

FIG. 21 shows a measured data supporting the read window improvement by the embodiments of the present disclosure.

When compared with the constant step size, the variable step size shows 9% improvement. This data was taken after applying adjusting the step size for the program state P1 only on the PLC emulation program.

Although the foregoing embodiments have been illustrated and described in some detail for purposes of clarity and understanding, the present disclosure is not limited to the embodiments provided. There are many alternative ways of implementing the invention, as one skilled in the art will appreciate in light of the foregoing disclosure. The disclosed embodiments are thus illustrative, not restrictive. The present disclosure is intended to embrace all modifications and alternatives of the disclosed embodiments. Furthermore, the disclosed embodiments may be combined to form additional embodiments.

Indeed, implementations of the subject matter and the functional operations described in the present disclosure can be implemented in various systems, digital electronic circuitry, or in computer software, firmware, or hardware, including the structures disclosed in this specification and their structural equivalents, or in combinations of one or more of them. Embodiments of the subject matter described in this specification can be implemented as one or more computer program products, i.e., one or more modules of computer program instructions encoded on a tangible and non-transitory computer readable medium for execution by, or to control the operation of, a data processing apparatus. The computer readable medium can be a machine-readable storage device, a machine-readable storage substrate, a memory device, a composition of matter affecting a machine-readable propagated signal, or a combination of one or more of them. The term “data processing unit” or “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them.

A computer program (also known as a program, software, software application, script, or code) can be written in any form of programming language, including compiled or interpreted languages, and it can be deployed in any form, including as a stand-alone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and one or more processors of any type of digital computer. Generally, a processor will receive instructions and data from a read only memory or a random-access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of non-volatile memory, media and memory devices, including by way of example semiconductor memory devices, e.g., EPROM, EEPROM, and flash memory devices. The processor and the memory can be supplemented by, or incorporated in, special purpose logic circuitry.

While the present disclosure contains many specifics, these should not be construed as limitations on the scope of any invention or of what may be claimed, but rather as descriptions of features that may be specific to particular embodiments of particular inventions. Certain features that are described in the present disclosure in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations, one or more features from a combination can in some cases be excised from the combination, and the combination may be directed to a sub-combination or a variation of a sub-combination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in the present disclosure should not be understood as requiring such separation in all embodiments.

Only a few embodiments and examples are described and other embodiments, enhancements and variations can be made based on what is described and illustrated in the present disclosure. Furthermore, the embodiments may be combined to form additional embodiments.

What is claimed is:

1. An operating method of a storage device, the operating method comprising performing plural program loops on target memory cells for an n-th program state, according to a double verify program scheme, n being a natural number greater than 1 and less than N corresponding to a number of program states, wherein:
the plural program loops include applying, to the target memory cells, program pulses having a step size for the n-th program state according to an incremental step pulse program scheme; and
the plural program loops include varying the step size according to the n-th program state.

2. The operating method of claim 1,
wherein the varying includes:
applying the program pulse having a base value as an initial value of the step size for the n-th program state; and
adjusting the step size from the initial value to a pre-updated value when, for the first time, one of the target memory cells has a higher threshold voltage than a pre-verification level for the n-th program state, and
wherein the pre-updated value is a sum of the base value and a pre-offset value.

3. The operating method of claim 2, wherein:
the varying further includes adjusting the step size from the pre-updated value to a main-updated value when, for the first time, one of the target memory cells has a higher threshold voltage than a main verification level for the n-th program state; and
the main-updated value is a sum of the base value and a main-offset value.

4. The operating method of claim 3, wherein the varying further includes keeping the step size to the main-updated value until all the target memory cells pass the main verification level for the n-th program state.

5. The operating method of claim 4, wherein:
the initial value is equal to or greater than the main-updated value; and
the main-updated value is equal to or greater than the pre-updated value.

6. The operating method of claim 5, wherein the n-th program state is a relatively lower program state among N program states.

7. The operating method of claim 4, wherein:
the initial value is equal to or less than the pre-updated value; and
the pre-updated value is equal to or less than the main-updated value.

8. The operating method of claim 7, wherein the n-th program state is a relatively higher program state among N program states.

9. The operating method of claim 4, wherein the varying further includes:
defining, as a first loop base value, the step size currently having one of the initial value, pre-updated value and main-updated value at a moment when a number of advanced program loops exceeds a first threshold; and
replacing the base value with a sum of the first loop base value and a negative first offset value as a first updated base value, to continue performing the plural program loops with the first updated base value for the step size to have one of the first updated base value, a sum of the first loop base value and the pre-offset value as the pre-updated value and a sum of the first loop base value and the main-offset value as the main-updated value.

10. The operating method of claim 9,
wherein the varying further includes:
defining, as a second loop base value, the step size currently having one of the first updated base value, pre-updated value and main-updated value at a moment when the number of advanced program loops exceeds a second threshold greater than the first threshold; and
replacing the first loop base value with a sum of the second loop base value and a negative second offset value as a second updated base value, to continue performing the plural program loops with the second updated base value for the step size to have one of the second updated base value, a sum of the second loop base value and the pre-offset value as the pre-updated value and a sum of the second loop base value and the main-offset value as the main-updated value, and
wherein an absolute value of the second offset value is greater than an absolute value of the first offset value.

11. An operating method of a storage device, the operating method comprising performing plural program loops on target memory cells for an n-th program state within a j-th program state group, according to a double verify program scheme, n being a natural number greater than 1 and less than Nj corresponding to a number of program states included in each program state group, and j being a natural number greater than 1 to J corresponding to a number of program state groups, wherein:
the plural program loops include applying, to the target memory cells, program pulses having a step size for an n-th program state within the j-th program state group according to an incremental step pulse program scheme; and
the plural program loops include varying the step size according to each of the n-th program state and the j-th program state group.

12. The operating method of claim 11,
wherein the varying includes:
applying the program pulse having a sum of a base value and a group base offset value as a group initial value of the step size for the n-th program state within the j-th program state group; and
adjusting the step size from the group initial value to a pre-updated value when, for the first time, one of the target memory cells has a higher threshold voltage than a pre-verification level for the n-th program state within the j-th program state group, and
wherein the pre-updated value is a sum of the base value and a group pre-offset value.

13. The operating method of claim 12, wherein:
the varying further includes adjusting the step size from the pre-updated value to a main-updated value when, for the first time, one of the target memory cells has a higher threshold voltage than a main verification level for the n-th program state within the j-th program state group; and
the main-updated value is a sum of the base value and a group main-offset value.

14. The operating method of claim 13, wherein the varying further includes keeping the step size to the main-updated value until all the target memory cells pass the main verification level for the n-th program state within the j-th program state group.

15. The operating method of claim 14, wherein:
the base value is equal to or greater than the main-updated value;
the main-updated value is equal to or greater than the pre-updated value; and
the pre-updated value is equal to or greater than the group initial value.

16. The operating method of claim 15, wherein the j-th program state group is a relatively lower program state group among J program state groups.

17. The operating method of claim 14, wherein:
the base value is equal to or less than the group initial value;
the group initial value is equal to or less than the pre-updated value; and
the pre-updated value is equal to or less than the main-updated value.

18. The operating method of claim 17, wherein the j-th program state group is a relatively higher program state group among J program state groups.

19. The operating method of claim 14, wherein the varying further includes:
defining, as a first loop base value, the step size currently having one of the group initial value, pre-updated value and main-updated value at a moment when a number of advanced program loops exceeds a first threshold; and
replacing the base value with a sum of the first loop base value and a negative first offset as a first updated base value, to continue performing the plural program loops with the first updated base value for the step size to have one of the first updated base value, a sum of the first loop base value and the pre-offset value as the pre-updated value and a sum of the first loop base value and the main-offset value as the main-updated value.

20. The operating method of claim 19,
wherein the varying further includes:
defining, as a second loop base value, the step size currently having one of the first updated base value, pre-updated value and main-updated value at a moment when the number of advanced program loops exceeds a second threshold greater than the first threshold; and
replacing the first loop base value with a sum of the second loop base value and a negative second offset as a second updated base value, to continue performing the plural program loops with the second updated base value for the step size to have one of the second updated base value, a sum of the second loop base value and the pre-offset value as the pre-updated value and a sum of the second loop base value and the main-offset value as the main-updated value, and
wherein an absolute value of the second offset is greater than an absolute value of the first offset.
